(19) United States
(12) Patent Application Publication
(10) Pub. No.: US 2025/0318075 A1
(43) Pub. Date: Oct. 9, 2025

(54) INTERNAL CONNECTOR, LIQUID COOLING MECHANISM HAVING THE INTERNAL CONNECTOR, AND CHASSIS HAVING THE COOLING MECHANISM

(71) Applicant: Fulian Precision Electronics ( Tianjin ) Co., LTD., Tianjin (CN)

(72) Inventors: CHANG-JU WU, New Taipei (TW); CHIH-MIN LIN, New Taipei (TW)

(21) Appl. No.: 18/960,015

(22) Filed: Nov. 26, 2024

(30) Foreign Application Priority Data
Apr. 9, 2024 (CN) 202410420969.8

(51) Int. Cl. H05K 7/20

(52) U.S. Cl. CPC H05K 7/20272

(57) ABSTRACT

An internal connector has a connecting base with first and second portions. The first portion has a connecting end, closed end and a communication port. A manifold's insertion end extends into the first portion. When the insertion end moves towards the closed end and is covered by the closed end or the manifold's outer wall covers the port, the second portion disconnects from the manifold.

### FIELD

This application relates to liquid cooling technology, specifically to an internal connector, a liquid cooling mechanism having the connector, and a chassis having the liquid cooling mechanism.

### BACKGROUND

Servers may use liquid cooling mechanisms for heat dissipation. However, the liquid cooling mechanisms may have risks related to leakage. Liquid cooling mechanisms may be provided with external connectors. When leakage occurs, the external connector may automatically disconnect from the source of liquid flow. However, a supply pipe connected to the connector may not be easily bent to provide the necessary space for the connector to disconnect, thus the connector may fail to disconnect from the liquid flow.

### BRIEF DESCRIPTION OF THE DRAWINGS

Implementations of the present technology will now be described, by way of example only, with reference to the attached FIG.s, wherein:

FIG. 1 is a diagram of a chassis provided by an embodiment of the present disclosure.

FIG. 2 is a diagram showing portions of the chassis in FIG. 1.

FIG. 3 is a diagram of an internal connector in FIG. 2 being extended.

FIG. 4 is an exploded view of the internal connector in FIG. 3.

FIG. 5 is a cross-sectional view of the internal connector in FIG. 3 along a line A-A.

FIG. 6 is a diagram of the internal connector in FIG. 2 being contracted.

FIG. 7 is a cross-sectional view of the internal connector in FIG. 6 along a line B-B.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiment described herein. However, it will be understood by those of ordinary skill in the art that the embodiment described herein can be practiced without these specific details. In other instances, methods, procedures, and components have not been described in detail so as not to obscure the related relevant feature being described. Also, the description is not to be considered as limiting the scope of the embodiment described herein. The drawings are not necessarily to scale and the proportions of certain portions have been exaggerated to better illustrate details and features of the present disclosure.

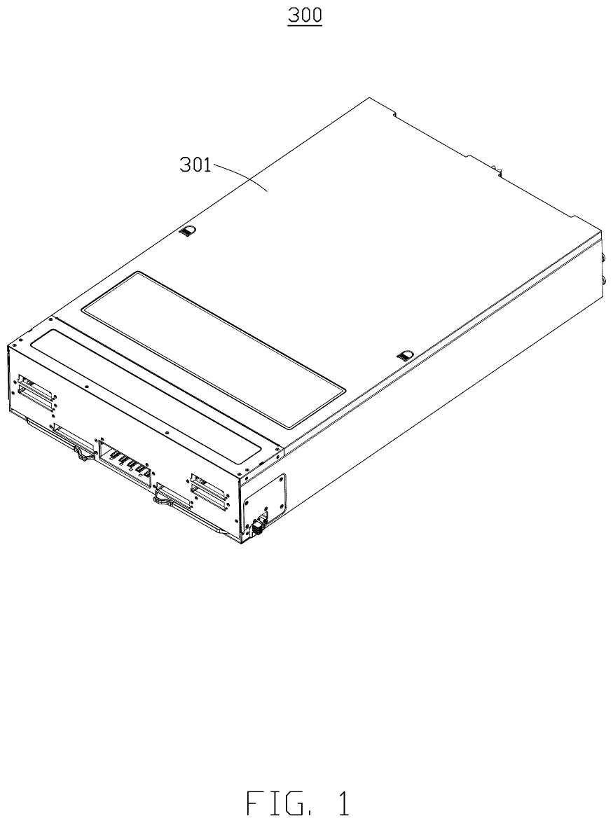

Referring to FIG. 1, a chassis 300 is provided according to an embodiment of this application. The chassis 300 may be used for accommodating a heat-generating device, such as a server.

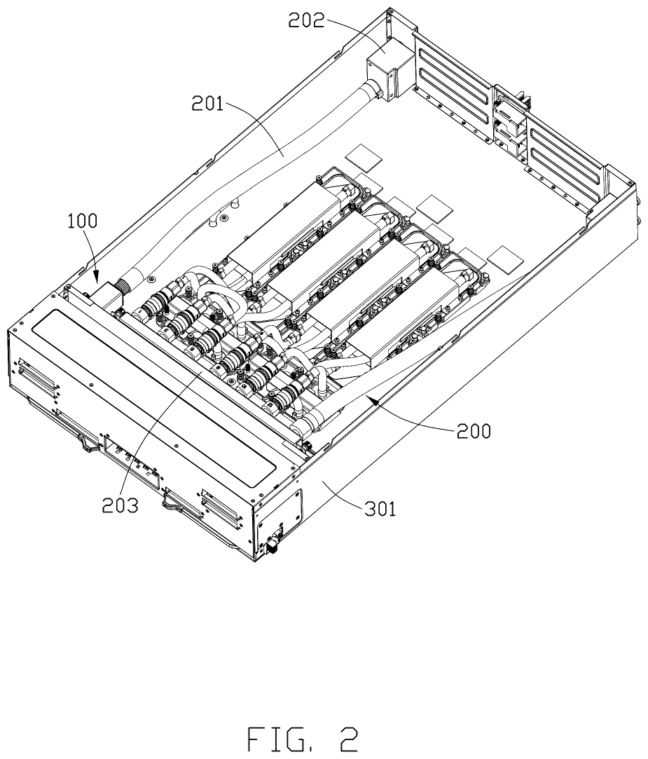

Referring to FIGS. 1 and 2, in one embodiment, the chassis 300 includes a housing 301 and a liquid cooling mechanism 200. The liquid cooling mechanism 200 is arranged inside the housing 301. The liquid cooling mechanism 200 is configured to cool the heat-generating device inside the chassis 300.

Referring to FIG. 2, in one embodiment, the liquid cooling mechanism 200 includes a supply pipe 201 and an external connector 202. The supply pipe 201 is connected to the external connector 202. The external connector 202 is connected to an external device. The supply pipe 201 is configured to convey a liquid. When liquid leakage occurs, the external connector 202 automatically disconnects the supply pipe 201 from the external device, thereby avoiding continuous liquid leakage.

Referring to FIG. 2, in one embodiment, the liquid cooling mechanism 200 further includes a liquid flow controller 203. One end of the supply pipe 201 is connected to the external connector 202, and the other end of the supply pipe 201 is connected to the liquid flow controller 203. The liquid flow controller 203 is used to control a flow rate, a flow volume, and a flow direction of the liquid within the liquid cooling mechanism 200.

Referring to FIGS. 2, 3, and 6, in one embodiment, the liquid cooling mechanism 200 further includes an internal connector 100. The internal connector 100 and the external connector 202 are respectively connected to both ends of the supply pipe 201. The internal connector 100 is configured to allow telescopic movement of the supply pipe 201 along its axial direction.

When the external connector 202 performs a disconnecting action, the internal connector 100 allows the supply pipe 201 to move, thereby providing the necessary space for the external connector 202 to perform the disconnecting action. When the external connector 202 reconnects, the internal connector 100 can maintain a communication state between the supply pipe 201 and the liquid flow controller 203.

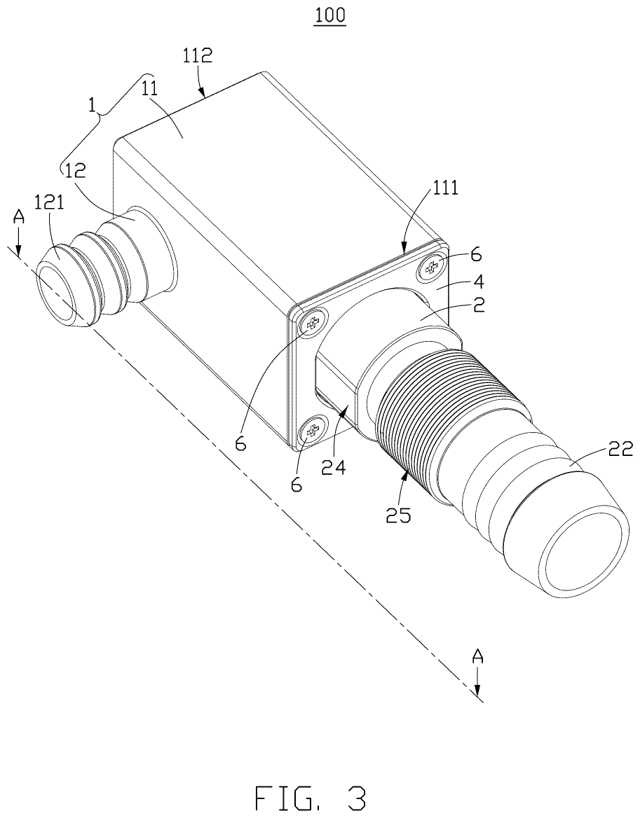

Referring to FIGS. 3 to 5, in one embodiment, the internal connector 100 includes a connecting base 1 and a manifold 2. The manifold 2 is inserted into the connecting base 1 and is configured to move relative to the connecting base 1. The manifold 2 is configured to connect with the supply pipe 201.

The connecting base 1 includes a first portion 11 and a second portion 12. The first portion 11 includes a connecting end 111 and a closed end 112. The connecting end 111 defines an opening. The opening is used for inserting the manifold 2. The closed end 112 blocks the first portion 11. The first portion 11 defines a communication port 113. The communication port 113 is arranged between the connecting end 111 and the closed end 112. The second portion 12 is connected to an outer wall of the first portion 11 and communicates with the first portion 11 through the communication port 113.

The manifold 2 includes an insertion end 21. The insertion end 21 extends through the connecting end 111 and is inserted into the first portion 11. The insertion end 21 defines an opening extending towards the extension direction of the manifold 2, allowing communication with the first portion 11 and the second portion 12. The insertion end 21 is capable of moving in relative to the first portion 11 along its extension direction and pass over the communication port 113.

The manifold 2 communicates with the second portion 12 through the first portion 11, so that the liquid cooling mechanism 200 where the internal connector 100 is located forms a circulating path. The insertion end 21 can move within the first portion 11 to allow the supply pipe 201 connected to the manifold 2, thereby providing sufficient space for the external connector 202 to perform a disconnecting action. The communication port 113 is arranged on a side wall of the first portion 11, allowing the insertion end 21 to move towards the closed end 112 and pass over the communication port 113 relative to the first portion 11.

Along the extension direction of the first portion 11, when the insertion end 21 moves towards the closed end 112 such that the closed end 112 covers the insertion end 21 or an outer wall of the manifold 2 covers the communication port 113, the second portion 12 is disconnected from the manifold 2.

When the insertion end 21 moves towards the closed end 112 and passes over the communication port 113, the insertion end 21 can be blocked by the closed end 112 to prevent liquid from flowing through the insertion end 21, or the communication port 113 can be blocked by the manifold 2 to prevent liquid from flowing through the communication port 113. This facilitates cutting off the liquid path between the insertion end 21 and the communication port 113. When the external connector 202 performs a disconnecting action, it drives the insertion end 21 to move towards the closed end 112, causing the insertion end 21 to pass over the communication port 113, thereby, the second portion 12 is disconnected from the manifold 2, which helps prevent liquid from leaking from the other end of the manifold 2 opposite to the insertion end 21. When reconnection between the manifold 2 and the second portion 12 is needed, it is only necessary to move the insertion end 21 towards the connecting end 111 to restore the liquid flow path.

By causing the manifold 2 to move relative to the connecting base 1 to cut off the communication between the manifold 2 and the connecting base 1, the manifold 2 can synchronize with the disconnection displacement of the external connector 202, and prevent liquid leakage.

Referring to FIG. 3, in one embodiment, the first portion 11 and the second portion 12 are substantially distributed in an “L” shape.

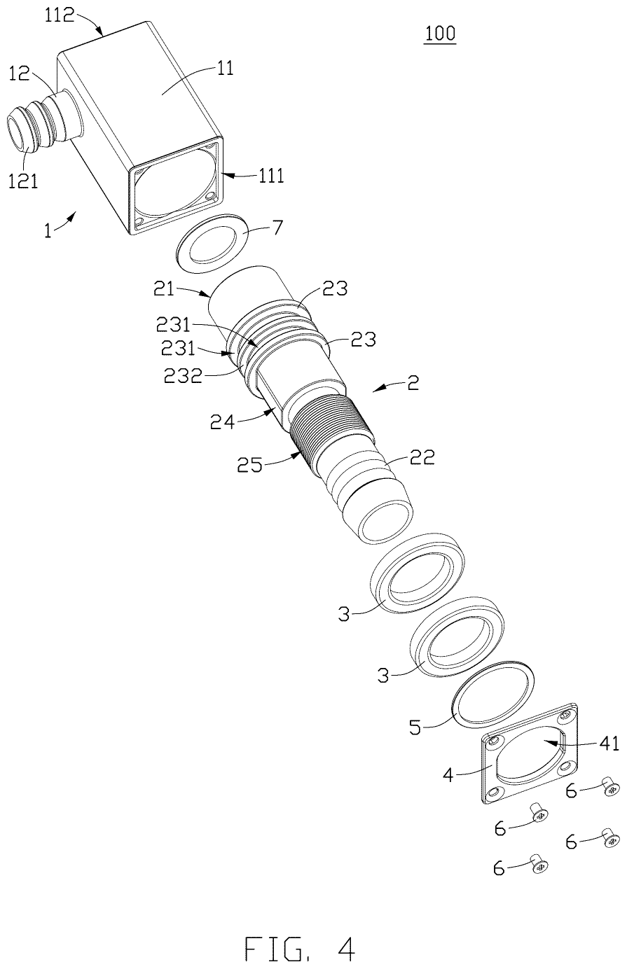

Referring to FIGS. 2 and 4, in one embodiment, the manifold 2 and the external connector 202 are respectively connected to both ends of the supply pipe 201. The end of the manifold 2 opposite to the insertion end 21 along its extension direction is connected to the supply pipe 201. The second portion 12 is configured to connect with other devices, such as the liquid flow controller 203.

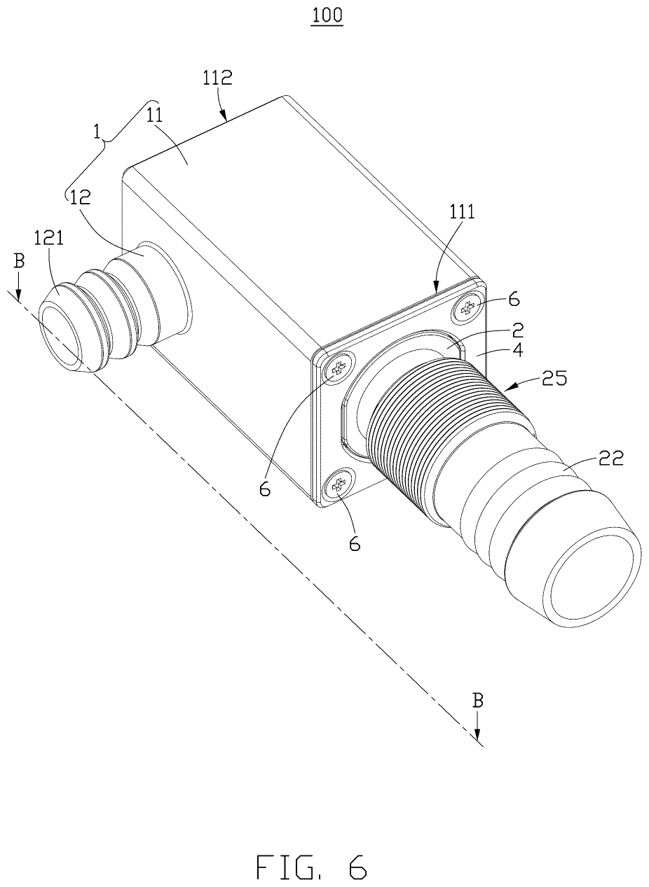

Referring to FIGS. 3 and 6, in one embodiment, the outer wall of the manifold 2 is provided with first barbs 22 to facilitate insertion of other structures, such as the supply pipe 201. An outer wall of the second portion 12 is provided with second barbs 121 to facilitate insertion of other structures, such as the liquid flow controller 203. The parts where the first barbs 22 are located are hose structures, and the parts where the second barbs 121 are located are hose structures.

Referring to FIGS. 4, 5, and 7, in one embodiment, the manifold 2 is provided with multiple ribs 23. The ribs 23 are distributed at intervals along an extension direction of the manifold 2. Each rib 23 is annularly arranged around a circumference of the manifold 2. The internal connector 100 further includes a first sealing member 3. The first sealing member 3 is arranged among the multiple ribs 23. When the insertion end 21 moves within the first portion 11, the first sealing member 3 abuts against an inner wall of the first portion 11. The first sealing member 3 is at least partially always located between the communication port 113 and the connecting end 111. In other embodiments, when the manifold 2 is inserted into the first portion 11, the extension direction of the manifold 2 is parallel to that of the first portion 11.

The first sealing member 3 is arranged on the outer wall of the manifold 2, forming a seal between the manifold 2 and the first portion 11. Whether the manifold 2 is connected to the second portion 12 or not, this helps prevent liquid from leaking towards the connecting end 111 between the manifold 2 and the first portion 11. The ribs 23 on the outer wall of the manifold 2 constrain the relative position of the first sealing member 3, improving the stability of the first sealing member 3 relative to the manifold 2 when the manifold 2 moves relative to the first portion 11. This reduces the possibility of the first sealing member 3 moving and disengaging from the first portion 11 or the manifold 2, thereby enhancing the sealing and waterproof effect of the internal connector 100. Each rib 23 continuously extends around the outer wall of the manifold 2. In other embodiment, each rib 23 can be arranged in segments spaced around the outer wall of the manifold 2.

Referring to FIGS. 4, 5, and 7, in one embodiment, the manifold 2 is provided with two ribs 23. There are multiple recessed portions 231 between the two ribs 23. A protruding portion 232 is formed between adjacent recessed portions 231. Each first sealing member 3 is arranged at a recessed portion 231. The recessed portions 231, in cooperation with the protruding portions 232, can limit the position of each first sealing member 3. Each protruding portion 232 protrudes from the manifold 2 to a height less than that of the ribs 23 to reduce the difficulty of the first sealing member 3 passing over the protruding portions 232 during assembly.

In one embodiment, the first sealing member 3 is made of PTFE (Polytetrafluoroethylene). The PTFE material allows the first sealing member 3 to achieve sealing between the manifold 2 and the first portion 11 while reducing friction between them, facilitating the manifold 2 to move relative to the first portion 11, which is beneficial for the external connector 202 to perform disconnecting action.

Referring to FIGS. 4, 5, and 7, in one embodiment, the internal connector 100 further includes a cover plate 4. The cover plate 4 is detachably connected to the connecting end 111. The cover plate 4 is configured to stop the ribs 23 from disengaging from the first portion 11.

The cover plate 4 stops the ribs 23 from disengaging from the first portion 11, maintaining the inserted state between the manifold 2 and the first portion 11. Thus, when the insertion end 21 moves relative to the first portion 11, the first portion 11 always remains inside, allowing the first portion 11 to cooperate with the outer wall of the manifold 2 to prevent liquid from leaking towards the connecting end 111 between the first sub-portion 114 and the manifold 2. The cover plate 4, being detachable, can be removed from the connecting base 1 to facilitate assembling or disassembling the manifold 2 to or from the connecting base 1.

Referring to FIG. 4, in one embodiment, the cover plate 4 is provided with an insertion port 41. The manifold 2 is extended through the insertion port 41 and is inserted into the first portion 11. The diameter of the insertion port 41 is smaller than the inner diameter of the first portion 11 at the connecting end 111.

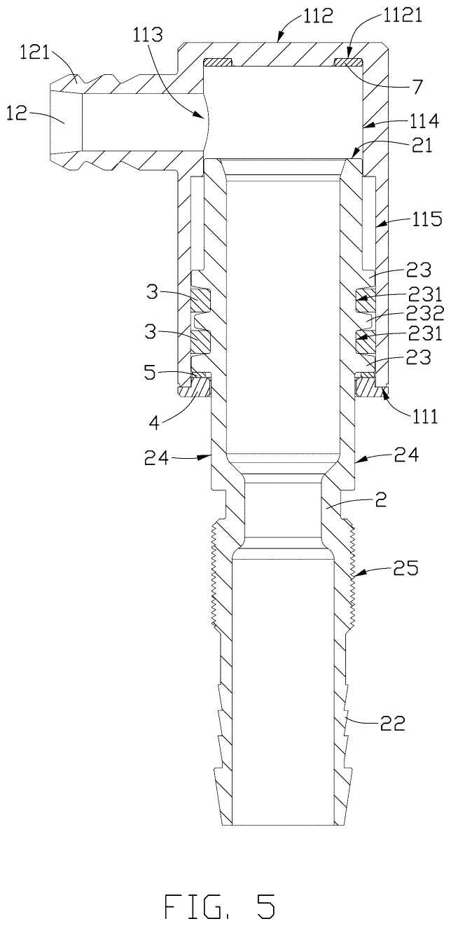

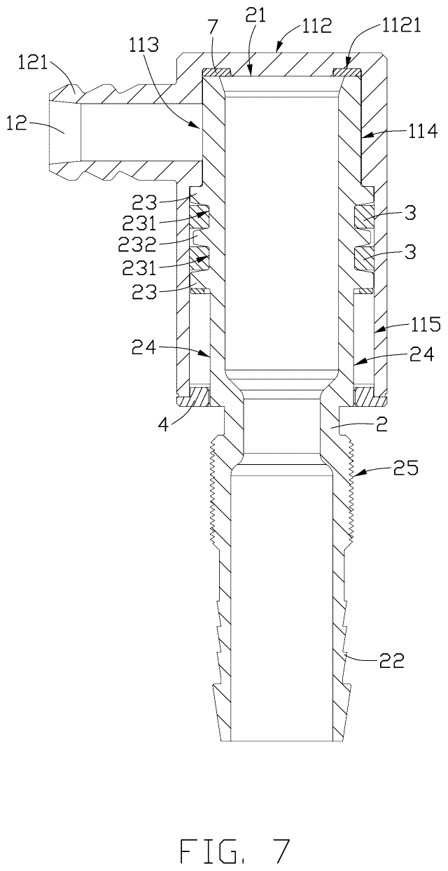

Referring to FIGS. 5 and 7, in one embodiment, the first portion 11 includes a first sub-portion 114 and a second sub-portion 115 that communicate with each other. The communication port 113 is arranged on the first sub-portion 114. Along the extension direction of the first portion 11, the first sub-portion 114 is closer to the closed end 112 than the second sub-portion 115. In a direction perpendicular to the extension direction of the first portion 11, the outer diameter of the ribs 23 is greater than the inner diameter of the first sub-portion 114 and less than the inner diameter of the second sub-portion 115.

An inner diameter of the second sub-portion 115 is larger than that of the first sub-portion 114, allowing the insertion end 21 to move within the first sub-portion 114 while permitting the ribs 23 to move within the second sub-portion 115. At the same time, the first sub-portion 114 is farther from the insertion end 21 compared to the second sub-portion 115, so the first sub-portion 114 can abut the part between the ribs 23 and the insertion end 21 of the manifold 2. On one hand, when it is necessary to disconnect the manifold 2 from the second sub-portion 115, the outer wall of the manifold 2 can block the communication port 113. On the other hand, when it is necessary for the manifold 2 to communicate with the second sub-portion 115, it helps prevent liquid from leaking towards the connecting end 111 between the first sub-portion 114 and the manifold 2.

Referring to FIGS. 5 and 7, in one embodiment, in a direction perpendicular to the extension direction of the first portion 11, the part of the outer wall of the manifold 2 between the insertion end 21 and the ribs 23 is close to the first sub-portion 114, and the outer wall of the ribs 23 is close to the second sub-portion 115. This can improve the stability of the manifold 2 moving relative to the first portion 11 and reduce the possibility of liquid flowing between the outer wall of the manifold 2 and the inner wall of the first portion 11.

Referring to FIG. 3 and FIG. 5, in one embodiment, along the extension direction of the first portion 11, a distance between the closed end 112 and the ribs 23 is equal to or slightly greater than a distance between the closed end 112 and the second sub-portion 115. Here, the distance between the closed end 112 and the ribs 23 refers to the distance to the rib 23 closest to the insertion end 21; the distance between the closed end 112 and the second sub-portion 115 refers to the distance to the end of the second sub-portion 115 closest to the closed end 112.

When the insertion end 21 moves towards the closed end 112, the ribs 23 move together with it. The boundary between the second sub-portion 115 and the first sub-portion 114 forms a stepped surface, which can stop the ribs 23 from moving further towards the closed end 112, providing a buffer when the insertion end 21 rushes towards the closed end 112. This enhances the service life of the internal connector 100, reduces wear between the insertion end 21 and the closed end 112, and improves the anti-leakage effect.

Referring to FIGS. 6 and 7, in one embodiment, along the extension direction of the first portion 11, the distance between the cover plate 4 and the ribs 23 is less than the distance between the cover plate 4 and the first sub-portion 114. Here, the distance between the cover plate 4 and the ribs 23 refers to the distance to the rib 23 farthest from the insertion end 21; the distance between the cover plate 4 and the first sub-portion 114 refers to the distance to the end of the first sub-portion 114 closest to the connecting end 111.

When the ribs 23 are stopped by the cover plate 4 and cannot continue moving towards the connecting end 111, the insertion end 21 still remains inside the first portion 11. This helps ensure that the first portion 11 can always cooperate with the outer wall of the manifold 2 to prevent liquid from leaking towards the connecting end 111 between the first sub-portion 114 and the manifold 2.

Referring to FIGS. 4, 5, and 7, in one embodiment, the internal connector 100 further includes a second sealing member 5. The second sealing member 5 is annularly arranged on the manifold 2 and located between the ribs 23 and the cover plate 4.

When the ribs 23 move towards the cover plate 4, they can move to clamp the second sealing member 5 between the ribs 23 and the cover plate 4, thereby enhancing the sealing effect between the manifold 2 and the cover plate 4.

Referring to FIG. 4, in one embodiment, the second sealing member 5 is an O-ring. While enhancing the sealing effect, it can also provide a buffering effect when the cover plate 4 stops the movement of the ribs 23.

Referring to FIGS. 3 and 4, in one embodiment, the internal connector 100 further includes a fastener 6. The fastener 6 connects the cover plate 4 and the connecting base 1. By providing the fastener 6, the cover plate 4 is fixedly connected to the connecting base 1. The fastener 6 includes screws and nuts. In other embodiment, the cover plate 4 can be connected to the connecting base 1 by snap-fit or threaded connection.

Referring to FIGS. 3 and 4, in one embodiment, the outer wall of the manifold 2 is provided with a cutting plane 24 and a threaded surface 25. The cutting plane 24 is closer to the insertion end 21 than the threaded surface 25.

By providing the threaded surface 25, it facilitates the manifold 2 to be fixedly connected with other structures, such as the supply pipe 201. By providing the cutting plane 24, it facilitates constraining the rotation of the manifold 2, which is beneficial for the manifold 2 to be connected with other structures through the threaded surface 25. The threaded surface 25 and the cutting plane 24 cooperate with each other to enhance the connection stability between the manifold 2 and other structures, helping to prevent liquid leakage. At the same time, by restricting the rotation of the manifold 2 relative to the connecting base 1, it helps avoid wear of the sealing structures of the internal connector 100.

Referring to FIG. 4, in one embodiment, the cover plate 4 cooperates with the cutting plane 24 to stop the manifold 2 from rotating relative to the connecting base 1. The diameter shape of the insertion port 41 of the cover plate 4 is profiled to the outer contour of the part of the manifold 2 where the cutting plane 24 is located.

In one embodiment, referring to FIGS. 3 and 5, when the manifold 2 is at the position where the cover plate 4 stops the ribs 23, the distance between the insertion end 21 and the closed end 112 is 15 mm, leaving enough space for liquid to flow between the manifold 2 and the second portion 12. Referring to FIGS. 6 and 7, when the manifold 2 is at the position where the closed end 112 stops the insertion end 21, the distance between the threaded surface 25 near the cover plate 4 side and the cover plate 4 is 2 mm, helping to avoid the structure connected to the threaded surface 25 from impacting the cover plate 4.

Referring to FIGS. 4, 5, and 7, in one embodiment, the internal connector 100 further includes a third sealing member 7. The third sealing member 7 is arranged on the closed end 112. The insertion end 21 can move to abut against the third sealing member 7.

The insertion end 21 abuts against the third sealing member 7, thereby enhancing the sealing effect between the insertion end 21 and the closed end 112. When the manifold 2 is in a state disconnected from the second portion 12, this prevents liquid from flowing through the insertion end 21, enhancing the anti-leakage effect of the internal connector 100.

Referring to FIG. 4, in one embodiment, the third sealing member 7 is an O-ring. While enhancing the sealing effect, it can also provide a buffering effect when the closed end 112 stops the movement of the insertion end 21.

Referring to FIGS. 4, 5, and 7, in one embodiment, the closed end 112 is provided with a groove 1121. The third sealing member 7 is arranged within the groove 1121. The groove 1121 can constrain the relative position of the third sealing member 7, maintaining the third sealing member 7 fixed relative to the closed end 112 when the insertion end 21 moves away from the closed end 112. This helps prevent the third sealing member 7 from disengaging from the closed end 112 and affecting the next movement of the insertion end 21 towards the closed end 112.

Referring to FIGS. 3 and 5 to 7, in one embodiment, the working principle of the internal connector 100 is as follows: when leakage occurs at other positions of the liquid cooling mechanism 200 or the chassis 300, the manifold 2 moves towards the closed end 112, and the connecting base 1 contracts to leave sufficient space for the external connector 202 to perform the disconnecting action. The insertion end 21 abuts against the third sealing member 7 arranged on the closed end 112 to prevent liquid from flowing between the second portion 12 and the manifold 2. When the liquid cooling mechanism 200 needs to restore the liquid cooling cycle, the manifold 2 moves away from the closed end 112, and the connecting base 1 extends to allow the external connector 202 to perform the connecting action. The ribs 23 are separated from the cover plate 4 only by the second sealing member 5, forming the largest space between the insertion end 21 and the closed end 112 for liquid flow.

The embodiment shown and described above are only examples. Many details are often found in the art such as the other features of the internal connector 100. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the portions within the principles of the present disclosure up to, and including the full extent established by the broad general meaning of the terms used in the claims. It will therefore be appreciated that the embodiment described above may be modified within the scope of the claims.

What is claimed is:

1. An internal connector 100, comprising:
a connecting base 1 comprising a first portion 11 and a second portion 12; and
a manifold 2, wherein:
the first portion comprises a connecting end 111 and a closed end 112, and defines a communication port 113 located between the connecting end and the closed end;
the second portion 12 communicates with the first portion 11 through the communication port;
the manifold 2 comprising an insertion end 21, the insertion end 21 extends through the connecting end 111 and is inserted into the first portion 11, and the insertion end 21 being movable relative to the first portion and movable pass the communication port 113; and
when the insertion end moves towards the closed end, such that the closed end covers the insertion end or an outer wall of the manifold covers the communication port, the second portion is disconnected from the manifold.

2. The internal connector of claim 1, wherein: the manifold further comprises a plurality of ribs distributed at intervals, each rib being annularly arranged around a circumference of the manifold;
the internal connector further comprises a first sealing member arranged between the plurality of ribs; and
when the insertion end moves within the first portion, the first sealing member abuts against an inner wall of the first portion and is at least partially located between the communication port and the connecting end.

3. The internal connector of claim 2, wherein:
the first portion further comprises a first sub-portion and a second sub-portion that communicate with each other;
the communication port is arranged on the first sub-portion;
along an extension direction of the first portion, the first sub-portion is closer to the closed end than the second sub-portion; and
in a direction perpendicular to the extension direction, an outer diameter of each of the plurality of ribs is greater than an inner diameter of the first sub-portion and less than an inner diameter of the second sub-portion.

4. The internal connector of claim 3, further comprising: a cover plate, wherein:
the cover plate is detachably connected to the connecting end;
the cover plate is configured, such that the plurality of ribs is prevented from disengaging the first portion; and
along the extension direction, a distance between the cover plate and each of the plurality of ribs is less than a distance between the cover plate and the first sub-portion.

5. The internal connector of claim 4, further comprising: a second sealing member, wherein
the second sealing member is annularly arranged on the manifold and located between the plurality of ribs and the cover plate.

6. The internal connector of claim 2, wherein the first sealing member is made of Polytetrafluoroethylene.

7. The internal connector of claim 1, wherein the outer wall of the manifold is provided with a cutting plane and a threaded surface, and the cutting plane is closer to the insertion end than the threaded surface.

8. The internal connector of claim 1, further comprising: a third sealing member arranged on the closed end, wherein the insertion end is capable of moving to abut against the third sealing member.

9. A liquid cooling mechanism, comprising:
a supply pipe;
an external connector; and
an internal connector comprising:
a connecting base comprising a first portion and a second portion; and
a manifold, wherein:
the first portion comprises a connecting end and a closed end, and defines a communication port located between the connecting end and the closed end;
the second portion communicates with the first portion through the communication port;
the manifold comprising an insertion end, the insertion end extends through the connecting end and is inserted into the first portion, and the insertion end being movable relative to the first portion and movable pass the communication port;
when the insertion end moves towards the closed end, such that the closed end covers the insertion end or an outer wall of the manifold covers the communication port, the second portion is disconnected from the manifold; and
the manifold and the external connector are respectively connected to opposite ends of the supply pipe, and an end of the manifold opposite to the insertion end is connected to the supply pipe.

10. The liquid cooling mechanism of claim 9, wherein the manifold further comprises a plurality of ribs distributed at intervals, each rib being annularly arranged around a circumference of the manifold;
the internal connector further comprises a first sealing member arranged between the plurality of ribs; and
when the insertion end moves within the first portion, the first sealing member abuts against an inner wall of the first portion and is at least partially located between the communication port and the connecting end.

11. The liquid cooling mechanism of claim 10, wherein:
the first portion further comprises a first sub-portion and a second sub-portion that communicate with each other;
the communication port is arranged on the first sub-portion;
along an extension direction of the first portion, the first sub-portion is closer to the closed end than the second sub-portion; and
in a direction perpendicular to the extension direction, an outer diameter of each of the plurality of ribs is greater than an inner diameter of the first sub-portion and less than an inner diameter of the second sub-portion.

12. The liquid cooling mechanism of claim 11, the internal connector further comprises a cover plate, wherein:
the cover plate is detachably connected to the connecting end;
the cover plate is configured to prevent the plurality of ribs from disengaging from the first portion;
along the extension direction of the first portion, a distance between the cover plate and each of the plurality of ribs is less than the distance between the cover plate and the first sub-portion.

13. The liquid cooling mechanism of claim 11, wherein the first sealing member is made of Polytetrafluoroethylene.

14. The liquid cooling mechanism of claim 9, wherein the outer wall of the manifold is provided with a cutting plane and a threaded surface, and the cutting plane is closer to the insertion end than the threaded surface.

15. The liquid cooling mechanism of claim 9, wherein the internal connector further comprises a third sealing member, the third sealing member is arranged on the closed end, the insertion end is capable of moving to abut against the third sealing member.

16. A chassis, comprising:
a housing;
a liquid cooling mechanism arranged inside the housing, wherein the liquid cooling mechanism comprises:
a supply pipe,
an external connector, and
an internal connector,
wherein the internal connector comprises:
a connecting base comprises a first portion and a second portion; and a manifold, wherein:
the first portion comprises a connecting end and a closed end, the first portion defines a communication port located between the connecting end and the closed end, the second portion communicates with the first portion through the communication port;
the manifold comprises an insertion end, the insertion end extends through the connecting end and is inserted into the first portion, the insertion end is movable relative to the first portion and passes over the communication port;
when the insertion end moves towards the closed end such that the closed end covers the insertion end or an outer wall of the manifold covers the communication port, the second portion is disconnected from the manifold;
the manifold and the connector are respectively connected to both ends of the supply pipe, an end of the manifold opposite to the insertion end is connected to the supply pipe.

17. The chassis of claim 16, wherein:
the manifold further comprises a plurality of ribs distributed at intervals, each rib being annularly arranged around a circumference of the manifold;
the internal connector further comprises a first sealing member arranged between the plurality of ribs; and
when the insertion end moves within the first portion, the first sealing member abuts against the inner wall of the first portion and is at least partially located between the communication port and the connecting end.

18. The chassis of claim 17, wherein:
the first portion further comprises a first sub-portion and a second sub-portion that communicate with each other;
the communication port is arranged on the first sub-portion;
along an extension direction of the first portion, the first sub-portion is closer to the closed end than the second sub-portion; and
in a direction perpendicular to the extension direction, an outer diameter of each of the plurality of ribs is greater than an inner diameter of the first sub-portion and less than an inner diameter of the second sub-portion.

19. The chassis of claim 17, wherein the internal connector further comprises a cover plate, wherein:
the cover plate is detachably connected to the connecting end;
the cover plate is configured to prevent the plurality of ribs from disengaging from the first portion;
along the extension direction of the first portion, a distance between the cover plate and each of the plurality of ribs is less than a distance between the cover plate and the first sub-portion.

20. The chassis of claim 19, wherein the internal connector further comprises a second sealing member, wherein the second sealing member is annularly arranged on the manifold and located between the plurality of ribs and the cover plate.
